(19) United States
(12) Patent Application Publication
(10) Pub. No.: US 2011/0285888 A1
(43) Pub. Date: Nov. 24, 2011

(54) IMAGE SENSING DEVICE

(75) Inventor: Yoshiyuki Okuda, Yamanashi (JP)

(73) Assignee: PIONEER CORPORATION, Kanagawa (JP)

(21) Appl. No.: 13/143,264

(22) PCT Filed: Dec. 25, 2009
(86) PCT No.: PCT/JP2009/071579

§ 371 Date: Aug. 10, 2011

(30) Foreign Application Priority Data
Jan. 9, 2009 (JP) PCTJP2009/050229

(51) Int. Cl. H04N 5/335

(52) U.S. Cl. 348/302; 348/E05.091

(57) ABSTRACT

An image device is provided. The image device includes a photoelectric conversion film current detector, an offset current source, an integrator, and a sampling unit. The photoelectric conversion film current detector is coupled to the photoelectric conversion film through a capacitor and detects photoelectric conversion film current that flows as holes generated in the photoelectric conversion film combine with electrons supplied from the electron supply source array to the photoelectric conversion film. The offset current source generates an offset current and superimposes the offset current on the photoelectric conversion film current. The integrator performs time-integration of the photoelectric conversion film current on which the offset current has been superimposed to generate an integration signal. The sampling unit samples the integration signal in each of respective pixel periods of the pixel regions, in which electrons are supplied to the pixel regions, to generate an image signal.

### BACKGROUND OF THE INVENTION

1. Field of the Invention

The present invention relates to an image sensing device that includes an image sensing element having both an array of electron supply sources and a photoelectric conversion film, and to a drive circuit that drives the image sensing element.

2. Description of the Related Art

An image sensing device, which includes an array of electron emission sources arranged in a matrix, each outputting electrons through application of an electric field, and a photoelectric conversion film, has been proposed (for example, Patent Document 1, see below). Examples of cold cathode electron emission sources include a High-efficiency Electron Emission Device (HEED) (for example, Non-Patent Document 1, see below) and a spint type cold cathode array. Another example is a carbon nanotube type. The HEED enables low-voltage driving and features a simple structure, and studies are underway on application of HEEDs to image sensing devices. Another electron supply element array is an array of switching transistors whose collectors or drains are connected to pixel regions of a photoelectric conversion film.

An example of the photoelectric conversion film is a High-gain Avalanche Rushing amorphous Photoconductor (HARP).

For example, in an image sensing device that uses an array of cold cathode electron emission elements, the electron emission elements emit electron beams to corresponding pixel regions of the photoelectric conversion film in respective drive periods. Such electron emission to each pixel region neutralizes holes stored in the pixel region according to the amount of light incident on the pixel region and a current generated through such neutralization is output through an electrode of the photoelectric conversion film, thereby detecting an image signal of the pixel region of the photoelectric conversion film. In the switching transistor array, an image signal is detected through current injection to the photoelectric conversion film instead of electron beam emission.

In a conventional technology, for example, as shown in FIG. 1, a neutralization current (a HARP current) output from an electrode of a photoelectric conversion film (a HARP electrode) is detected through a photoelectric conversion film current detector 101 and the neutralization current is converted into a voltage value and the voltage value passes through a Low Pass Filter (LPF) 102 to extract an image signal component. The most important advantage of this method is circuitry simplicity.

As shown in FIG. 2, when the amount of emitted electrons (or an HEED-emitted current) of each pixel varies, for example, when the amount of emitted electrons of a pixel PX(j) is smaller than the amount of emitted electrons of a pixel PX(j+1), the pulse height of a HARP current waveform in the pixel PX(j) having a smaller amount of emitted electrons is relatively low and a duration thereof T(j) is relatively long and the pulse height of a HARP current waveform in the pixel PX(j+1) having a larger amount of emitted electrons is relatively high and a duration thereof T(j+1) is relatively short. Since an integral value of the HARP current Ih(k)×T(k)=Qpx(k) (k=j,j+1) corresponds to the amount of holes stored in the corresponding pixel of the photoelectric conversion film, a DC component obtained after passing through the LPF 102 corresponds to the image signal of the pixel even when the amount of emitted electrons of each electron emission element varies.

However, the photoelectric conversion film (HARP) current waveforms after passing through the LPF 102 have irregularly modulated forms since the pulse widths and heights of the photoelectric conversion film current waveforms are different when the amount of emitted electrons of each electron emission element varies as shown in FIG. 2. Thus, frequency components due to such irregular modulation are generated in the band of the LPF 102 unlike the case where the HARP current pulses are uniform. Therefore, when the amount of emitted electrons of each electron emission element varies, there are problems in that noise occurs in the image signal, signal to noise ratio (S/N) is reduced, and image quality is degraded.

In addition, while demand for a high definition image sensing device has been increased, there has also been a need to realize a high image-quality, high performance image sensing device that can perform high-speed operation and has a high S/N ratio.
[Patent Document 1] Japanese Patent Application Publication No. H06-176704
[Non-Patent Document 1] Pioneer R&D, Vol. 17, No. 2, 2007, pp. 61-69

### DISCLOSURE OF THE INVENTION

### Problem to be Solved by the Invention

A high voltage for avalanche multiplication is applied to the photoelectric conversion film (HARP). The HARP current detector is coupled to the HARP electrode through a coupling capacitor and is configured to detect the HARP current. However, the HARP detection current causes potential variation in the HARP current detector, and the potential variation is applied to the HARP electrode through capacitive coupling of a coupling capacitor, thereby disturbing voltage applied to the photoelectric conversion film (HARP) and thus causing noise.

Therefore, the present invention has been made in view of the above problems, and it is an object of the present invention to provide an image sensing device that can perform high-speed operation and achieves high image quality and high performance with a high S/N ratio even when the amount of supplied electrons of each element of the electron supply source array varies.

It is another object of the present invention to provide an image sensing device that suppresses disturbance of voltage applied to a HARP due to potential variation in the HARP current detector and generates a stable and high-accuracy image signal.

### Measure Taken to Solve the Problem

An image sensing device according to the present invention includes a photoelectric conversion film that generates holes corresponding to incident light through avalanche multiplication, an electron supply source array including a plurality of electron supply sources arranged in a matrix, a scan driver that scans the electron supply source array to sequentially supply electrons to a plurality of pixel regions of the photoelectric conversion film, a photoelectric conversion film current detector coupled to the photoelectric conversion film through a capacitor, the photoelectric conversion film current detector detecting photoelectric conversion film current that flows as holes generated in the photoelectric conversion film combine with electrons supplied from the electron supply source array to the photoelectric conversion film, an offset current source which generates an offset current and superimposes the offset current on the photoelectric conversion film current; an integrator which performs time-integration of the photoelectric conversion film current on which the offset current has been superimposed to generate an integration signal; and a sampling unit that samples the integration signal in each of respective pixel periods of the pixel regions, in which electrons are supplied to the pixel regions, to generate an image signal.

### BRIEF DESCRIPTION OF THE DRAWINGS

FIG. 1 is a block diagram illustrating a configuration of a conventional technology in which a neutralization current is output from an electrode of a photoelectric conversion film and an image signal component is then extracted through a Low Pass Filter (LPF);

FIG. 2 illustrates how noise occurs in the band of the LPF due to irregular modulation when the amounts of electrons emitted from electron emission elements vary in the conventional technology shown in FIG. 1;

FIG. 3 is a cross-sectional view schematically illustrating a configuration of an HEED cold cathode HARP image sensing element;

FIG. 4 is a block diagram illustrating configurations of an HEED cold cathode array, Y-scan and X-scan drivers that drive the HEED cold cathode array, and a controller that controls all components of the device;

FIG. 5 is a partial cross-sectional view schematically illustrating a pixel portion of the active-matrix HEED cold cathode array to explain the structure of the active-matrix HEED cold cathode array;

FIG. 6 schematically illustrates a configuration of an image sensing device of Embodiment 1;

FIG. 7 is a block diagram illustrating a configuration of an image signal detector shown in FIG. 6;

FIG. 8 schematically illustrates output signal waveforms of the components of an image signal detector shown in FIG. 7 when the amounts of electrons emitted from HEED cold cathode array elements are equal;

FIG. 9 schematically illustrates output signal waveforms of the components of the image signal detector when the amounts of light incident on pixel regions of a HARP photoelectric conversion film are equal and the amounts of electrons emitted from HEED cold cathode array elements are different;

FIG. 10 is a block diagram illustrating a configuration of an image signal detector according to Embodiment 2 of the present invention;

FIG. 11 schematically illustrates output signal waveforms of the components of the image signal detector when the amounts of light incident on pixel regions of a HARP photoelectric conversion film are different and the amounts of electrons emitted from HEED cold cathode array elements are also different;

FIG. 12 schematically illustrates how the integrator performs an integration operation and an integral reset operation when dot-sequential scanning is performed on pixels PX(j) of a scan line Yk through a scanning operation of the scan line Yk in the X direction;

FIG. 13 is a circuit diagram illustrating an example of the circuit configuration of an integrator;

FIG. 14 is a circuit diagram illustrating another example of the circuit configuration of the integrator;

FIG. 15 is a circuit diagram illustrating another example of the circuit configuration of the integrator;

FIG. 16 is a block diagram illustrating a configuration of an integration type detector according to Embodiment 3 of the present invention;

FIG. 17 illustrates the relation between an emitter current Ie and a base-to-emitter voltage Vbe of a current receiving transistor; and

FIG. 18 schematically illustrates respective output signal waveforms of the components of Embodiment 3.

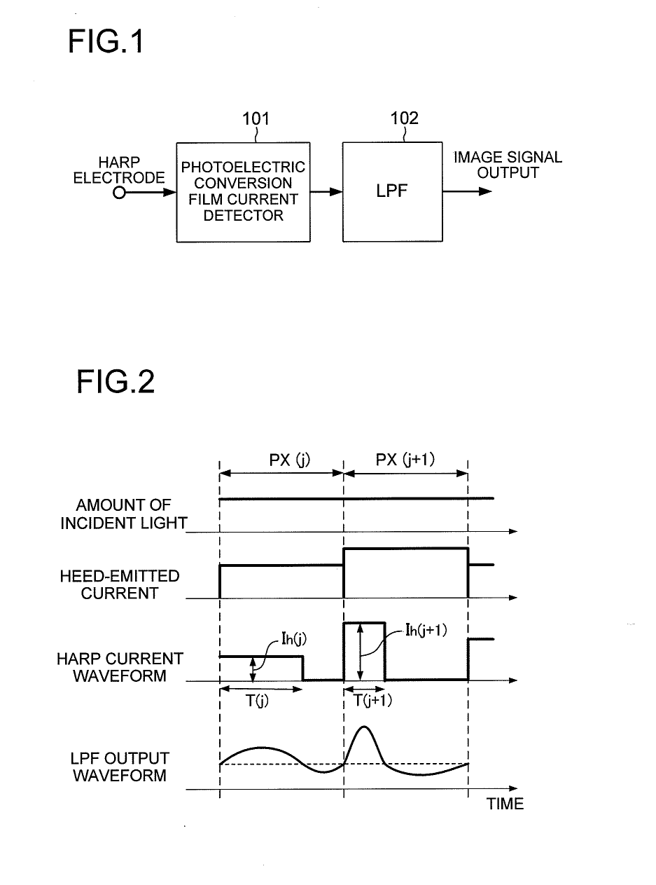

### MODE FOR CARRYING OUT THE INVENTION

The embodiments of the present invention will now be described with reference to the drawings. In the drawings described below, substantially identical or equivalent components are denoted by the same reference numerals.

### Embodiment 1

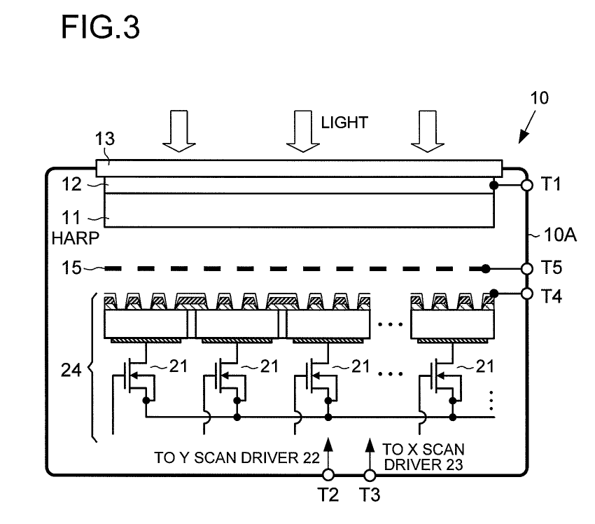

FIG. 3 is a cross-sectional view schematically illustrating a configuration of an HEED cold cathode HARP image sensing element 10. The HEED cold cathode HARP image sensing element 10, which will also be referred to as a “cold cathode image sensing element” for short, is an image sensing element which combines an active drive High-efficiency Electron Emission Device (HEED) with a High-gain Avalanche Rushing amorphous Photoconductor (HARP). More specifically, the cold cathode image sensing element 10 includes a HARP photoelectric conversion film 11, a HEED cold cathode array chip 24, and a mesh electrode (intermediate electrode) 15 which is disposed between the HARP photoelectric conversion film 11 and the HEED cold cathode array 20. As described later, the HEED cold cathode array chip 24 integrally includes an active-matrix HEED cold cathode array 20, which will hereinafter be referred to as an “HEED cold cathode array” for short, and a Y-scan driver 22 and an X-scan driver 23 which are not shown in FIG. 3. Although this embodiment is described with reference to the case where a photoelectric conversion film having a HARP structure and a cold cathode array having an HEED structure are used, these are only illustrative and a photoelectric conversion film having a different structure and a cold cathode having a different structure may also be used.

As shown in FIG. 3, the HARP photoelectric conversion film 11 is formed on a transparent conductive film 12 and the transparent conductive film 12 is formed on the transparent substrate 13. The HARP photoelectric conversion film 11 includes amorphous selenium (Se) as a main component and may also include another substance, for example, a compound semiconductor such as silicon (Si), lead oxide (PbO), cadmium selenium (CdSe), or gallium arsenide (GaAs). The transparent conductive film 12 may be formed of a tin oxide (SnO₂) film or an Indium Tin Oxide (ITO) film. As described later, a predetermined positive voltage, which will also be referred to as an “HARP potential or voltage”, is applied to the transparent conductive film 12 via a connection terminal (input/output terminal) T1 provided on a glass housing 10A.

The transparent substrate 13 may be formed of a substance that transmits light having wavelengths that are image-sensed by the cold cathode image sensing element 10. For example, the transparent substrate 13 is formed of a substance such as glass that transmits visible light when the cold cathode image sensing element 10 performs image sensing using visible light, and is formed of a substance such as sapphire or quartz glass that transmits ultraviolet light when the cold cathode image sensing element 10 performs image sensing with ultraviolet light. In addition, the transparent substrate 13 is formed of a substance that transmits x-rays, such as beryllium (Be), silicon (Si), boron nitride (BN), or aluminum oxide (Al₂O₃) when the cold cathode image sensing element 10 performs image sensing with x-rays.

The mesh electrode 15 has a plurality of openings and is formed of a known metal substance, alloy, semiconductor substance, or the like. A predetermined positive voltage, which will also be referred to as a “mesh voltage or potential”, is applied to the mesh electrode 15 via a connection terminal T5. The mesh electrode is an intermediate electrode provided for accelerating electrons and collecting surplus electrons.

As described later, gate electrodes of Metal Oxide Semiconductor (MOS) transistors, which drive the HEED, in the HEED cold cathode array 20 are connected to the X-scan driver 23, which is a horizontal scanning circuit, and source electrodes (S) thereof are connected to the Y-scan driver 22, which is a vertical scanning circuit, such that dot-sequential scanning (progressive scanning) is performed through the X-scan driver 23 and the Y-scan driver 22. The Y-scan driver 22 and the X-scan driver 23 are constructed as a single chip integrally with the HEED cold cathode array 20 on the HEED cold cathode array chip 24 and are provided inside the glass housing 10A (not illustrated). Signals or voltages required to drive the HEED cold cathode array chip are provided to the HEED cold cathode array chip 24 through connection terminals (input/output terminals) T2, T3, and T4 provided on the glass housing 10A.

All of these components are vacuum-encapsulated within the glass housing 10A sealed in frit glass or indium metal.

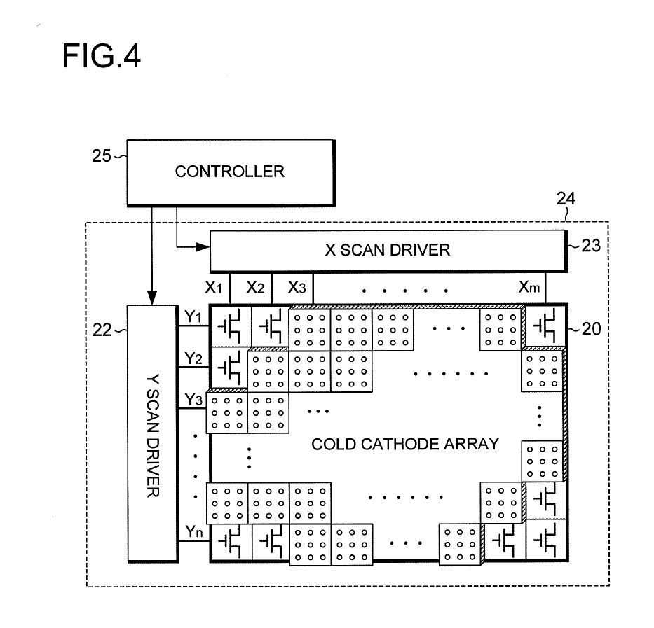

FIG. 4 is a block diagram illustrating configurations of the HEED cold cathode array 20, the Y-scan driver 22 and the X-scan driver 23 that drive the HEED cold cathode array 20, and the controller 25 that controls all components of the device. The Y-scan driver 22 and the X-scan driver 23 are integrally constructed as the single HEED cold cathode array chip 24. The controller 25 or other circuits described later may also be mounted on the chip.

As schematically shown in FIG. 4, the HEED cold cathode array 20 is constructed as an active-matrix Field Emitter Array (FEA) by integrally mounting an HEED cold cathode array directly on a drive circuit LSI that is formed on an Si wafer, and allows high-speed driving for image sensing operations (for example, operations with a drive pulse width of 10 ns or less per pixel) in which dot-sequential scanning is performed. The HEED cold cathode array 20 includes a plurality of pixels (n×m pixels) arranged in a matrix having “n” rows and “m” columns that are connected to scan drive lines (hereinafter simply referred to as “scan lines”) including “n” lines and “m” lines that are arranged respectively in the Y direction (i.e., the vertical direction) and the X direction (i.e., the horizontal direction). For example, the HEED cold cathode array 20 is constructed as a high-definition HEED cold cathode array of 640×480 pixels (i.e., VGA).

The Y-scan driver 22 and the X-scan driver 23 perform dot-sequential scanning and pixel driving based on control signals such as a vertical synchronization signal (V-Sync), a horizontal synchronization signal (H-Sync), and a clock signal (CLK) from the controller 25. That is, the Y-scan driver 22 and the X-scan driver 23 perform dot-sequential scanning such that the Y-scan driver 22 sequentially scans the scan lines (Yj, j=1, 2, . . . , n) in the Y direction and, when one scan line (Yk) is selected, the X-scan driver 23 sequentially scans the scan lines (Xi, i=1, 2, . . . , m) in the X direction to select and drive each pixel on the scan line (Yk).

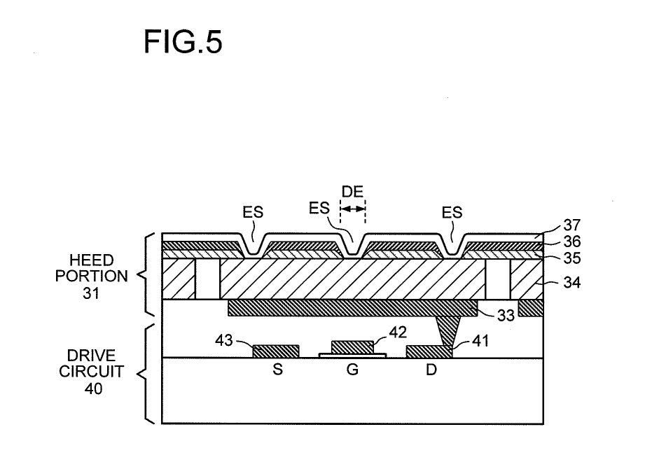

FIG. 5 is a partial cross-sectional view schematically illustrating an enlarged pixel portion of the active-matrix HEED cold cathode array 20 to explain the structure of the active-matrix HEED cold cathode array. The HEED cold cathode array 20 includes a drive circuit 40 and an HEED portion 31 which is formed on the top of the drive circuit 40 including a MOS transistor array after the drive circuit 40 and Y-scan and X-scan drivers 22 and 23 that drive and control the drive circuit 40 are formed.

As shown in FIG. 5, the HEED portion 31 is a Metal Insulator Semiconductor (MIS) cold cathode electron emission source that has a layered structure including a lower electrode 33, a silicon (Si) layer 34, a silicon oxide (SiOₓ) layer 35, an upper electrode 36 formed of, for example, tungsten (W), and a carbon (C) layer 37. The upper electrode 36 of the HEED cold cathode array 20 is common to all pixels and the lower electrode 33 and the Si layer 34 are divided to electrically separate the pixels from each other.

The lower electrode 33 of the HEED portion 31 is connected to a drain electrode D of a MOS transistor of the drive circuit 40 through a via hole. As described above, a gate electrode G and a source electrode S of the MOS transistor are connected to the X-scan driver 23 and the Y-scan driver 22. Switching of each pixel that emits electrons is performed by controlling the drain potential of the MOS transistor, i.e., the potential of the lower electrode 33 of each pixel of the HEED portion 31.

The number of pixels of the HEED cold cathode array 20 is, for example, 640×480 (VGA) and the size of one pixel is 20×20 μm². Emission sites ES, which are openings for electron emission, are provided in the surface portion of one pixel. For example, 3×3 emission sites ES having a diameter DE of about 1 μm (i.e., 3×3 1 μmφ emission sites ES) are formed in an 8×8 μm² area of one pixel. For example, an electron current of several microamperes (μA) is emitted (i.e., with an electron density of about 4 A/cm²) through one emission site ES. Such numerical values described in this embodiment are only illustrative and may be appropriately changed according to the type of an apparatus that uses the image sensing element, the resolution or sensitivity of the image sensing element, or the like.

### [Configuration and Operation of Image Sensing Device]

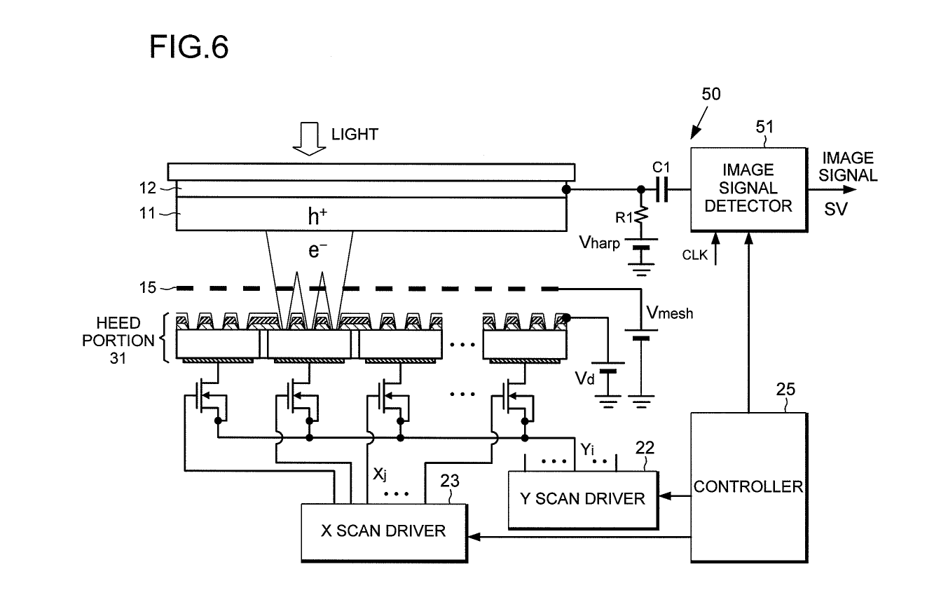

FIG. 6 schematically illustrates a configuration of an image sensing device 50 of the embodiment. The image sensing device 50 includes an image signal detector 51 and a controller 25 that controls the Y scan driver 22, the X scan driver 23, and the image signal detector 51.

As shown in FIG. 6, the image sensing device 50 is constructed such that an external power supply circuit is connected to a transparent conductive film 12, a predetermined positive voltage (HARP voltage) Vharp is applied to a HARP photoelectric conversion film 11, and a HARP signal is provided to the image signal detector 51 through a capacitor C1. The image sensing device 50 is also constructed such that a predetermined positive voltage (i.e., mesh voltage) Vmesh is applied to a mesh electrode 15. The image sensing device 50 is also constructed such that a predetermined positive voltage (i.e., HEED drive voltage) Vd is applied to an upper electrode 36 of an HEED portion 31. For example, the voltage values are Vharp=1.5 kV, Vmesh=470V, and Vd=23V. However, the present invention is not limited to these voltage values.

Next, a description is given of the operation of the image sensing device 50. When external light is incident on the HARP photoelectric conversion film 11 through the transparent conductive film 12, pairs of electrons and holes are generated according to the amount of the incident light at an inner portion of the HARP photoelectric conversion film 11 adjacent to the transparent conductive film 12. Among the pairs of electrons and holes, the holes are accelerated by a strong electric field, which is applied to the HARP photoelectric conversion film 11 through the transparent conductive film 12, and then successively collide with atoms included in the HARP photoelectric conversion film 11 to generate new pairs of electrons and holes. The holes thus generated through avalanche multiplication are accumulated on one side of the HARP photoelectric conversion film 11 which faces the HEED cold cathode array 20 (i.e., the side of the HARP photoelectric conversion film 11 opposite to the transparent conductive film 12), thereby forming a hole pattern corresponding to the incident optical image. A current generated when the hole pattern combines with electrons emitted by the HEED cold cathode array 20 is output as a HARP current corresponding to the incident optical image.

The components of the image sensing device 50, including a Y-scan driver 22, an X-scan driver 23, the image signal detector 51, and the controller 25, operate based on (i.e., in synchronization with) a clock signal (CLK) and perform the variety of operations described herein such as detection of a variety of signals, control of the drivers, and signal processing.

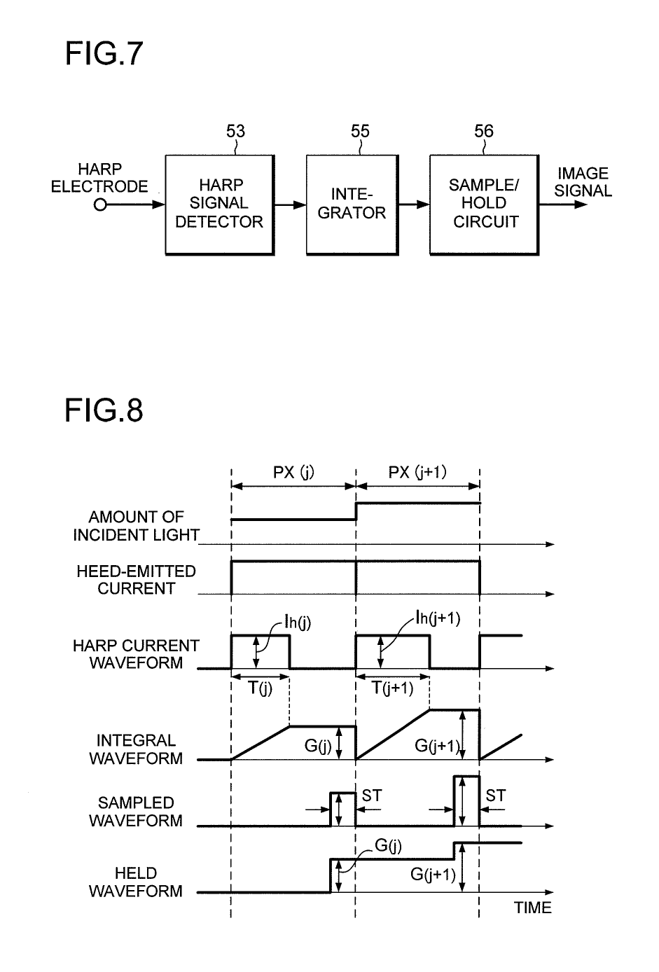

FIG. 7 is a block diagram illustrating a configuration of the image signal detector 51. The image signal detector 51 includes a HARP signal detector 53, an integrator 55, and a sample/hold circuit 56. As described above, these components of the image signal detector 51 operate based on a clock signal CLK under control of the controller 25.

FIG. 8 schematically illustrates output signal waveforms of the components of the image signal detector 51. For ease of explanation, the output signal waveforms are illustrated for two pixels PX(j) and PX(j+1). The periods of the pixels are also referred to as “pixel periods PX(j) and PX(j+1)”. In the case of an image sensing device of 640×480 pixels (VGA), the length of each pixel period is generally on the order of tens of nanoseconds, for example, 80 ns.

The HARP signal detector 53 is connected to the capacitor C1 provided with the HARP photoelectric conversion film 11 and detects a HARP current signal for each pixel based on the clock signal CLK. In the case illustrated in FIG. 8, the amounts of electrons emitted by elements corresponding to the pixels PX(j) and PX(j+1) of the HEED cold cathode array 20 are equal and the amounts of light incident on corresponding pixel regions of the HARP photoelectric conversion film 11 are different, more specifically, the amount of incident light of PX(j+1) is greater than the amount of incident light of PX(j). Here, HARP current values (pulse heights) are Ih(j)=Ih(j+1). T(j)<T(j+1) when the duration of the HARP current (i.e., neutralization current), which will hereinafter be referred to as an “HARP current period” is represented by T(j) for a j-th pixel.

The integrator 55 resets the integrated value when the pixel period terminates and calculates an integrated value of the HARP current for each of the pixel periods PX(j) and PX(j+1). The integrator 55 may be constructed using, for example, an operational amplifier. The integrator 55 may also be constructed using, for example, a circuit that utilizes current reception and capacitor charging.

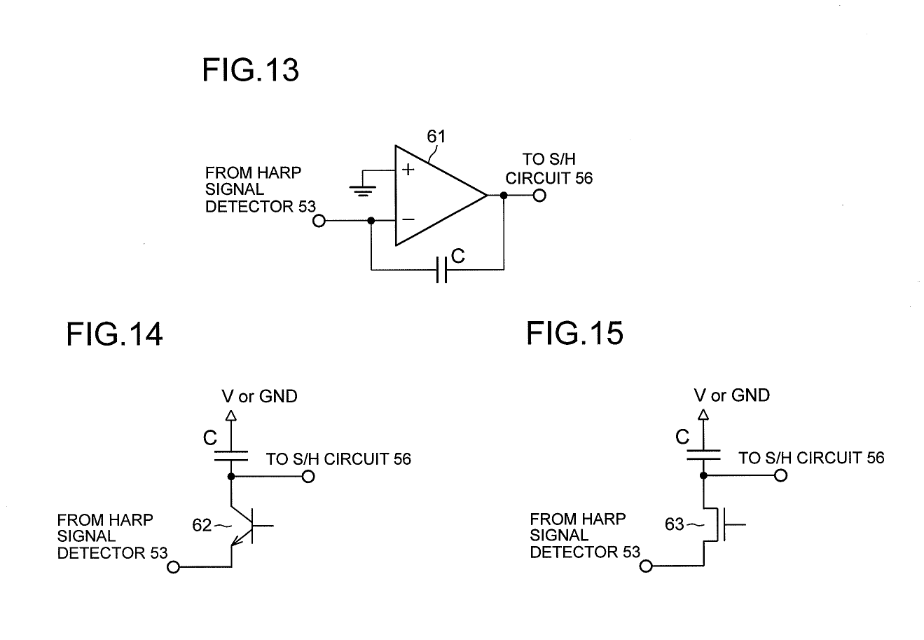

FIG. 13 is a circuit diagram illustrating an example circuit configuration of the integrator 55. The integrator 55 includes, for example, an operational amplifier 61 and a capacitor C. A non-inverting input (+) of the operational amplifier 61 is connected to ground (GND) and an inverting input (−) of the operational amplifier 61 is connected to an output thereof through a capacitor C. The output of the operational amplifier 61 is connected to a sample/hold (S/H) circuit 56. The inverting input (−) of the operational amplifier 61 is connected to the HARP signal detector 53 and a HARP current signal is provided to the inverting input (−). Accordingly, the HARP current signal from the HARP signal detector 53 is integrated by the integrator 55 and the integrated value (or integral) is provided to the sample/hold circuit 56. A resistor may also be provided in series between the HARP signal detector 53 and the input side of the operational amplifier 61, i.e., the inverting input (−).

A reset circuit (not shown) for discharging the capacitor C is provided in the integrator 55. As described above, each component of the image signal detector 51 including the integrator 55 operates under control of the controller 25. Under control of the controller 25, the integrated value of the integrator 55 is reset, for example, when the pixel period terminates as described in detail later.

FIGS. 14 and 15 illustrate another example of the integrator 55. Specifically, FIG. 14 illustrates an emitter input type integrator using a bipolar transistor 62 and a capacitor C. The HARP current signal from the HARP signal detector 53 is provided to an emitter of the bipolar transistor 62. A collector connected to the capacitor C is connected to the sample/hold circuit 56 and the integrated value of the HARP current signal is provided to the sample/hold circuit 56.

In addition, FIG. 15 illustrates a source input type integrator using a Field Effect Transistor (FET) 63 and a capacitor C. The HARP current signal from the HARP signal detector 53 is provided to a source of the FET 63. A drain of the FET 63 connected to the capacitor C is connected to the sample/hold circuit 56 and an integrated value of the HARP current signal is provided to the sample/hold circuit 56.

The configuration of the integrator 55 is not limited to the above examples. The integrator 55 only needs to be configured so as to integrate the HARP current signal and output the integrated value.

As shown in FIG. 8, integral waveforms of HARP currents of the pixel period PX(j) and the pixel period PX(j+1) become constant after times T(j) and T(j+1) elapse after the respective pixel periods of the pixel period PX(j) and the pixel period PX(j+1) start. That is, the integral waveforms of the HARP currents of the pixel period PX(j) and the pixel period PX(j+1) have constant integrated values G(j) and G(j+1) according to the amounts of light incident on the pixel regions after periods required to complete neutralization of holes stored in the pixel regions elapse. Thus, the integrated value G(k) (k=1, 2, j, . . . ) represents luminance for each pixel. Hereinafter, G(k) will also be referred to as a “pixel value”. The integrator 55 resets the integrated value when the pixel period terminates.

The sample/hold circuit 56 samples an integral waveform of a HARP current in a predetermined sampling period ST at an end portion of each pixel period and holds the sampled value. Alternatively, the sample/hold circuit 56 may include a peak detection circuit to detect a peak value of an integral waveform in each pixel period and hold the peak value. The following description is given with reference to an example in which the sample/hold circuit 56 samples and holds an integrated value at an end portion of each pixel period.

The sample/hold circuit 56 outputs the held value as an image signal SV. Accordingly, the image signal detector can generate an accurate image signal according to the amount of light incident on each pixel region of the HARP photoelectric conversion film 11.

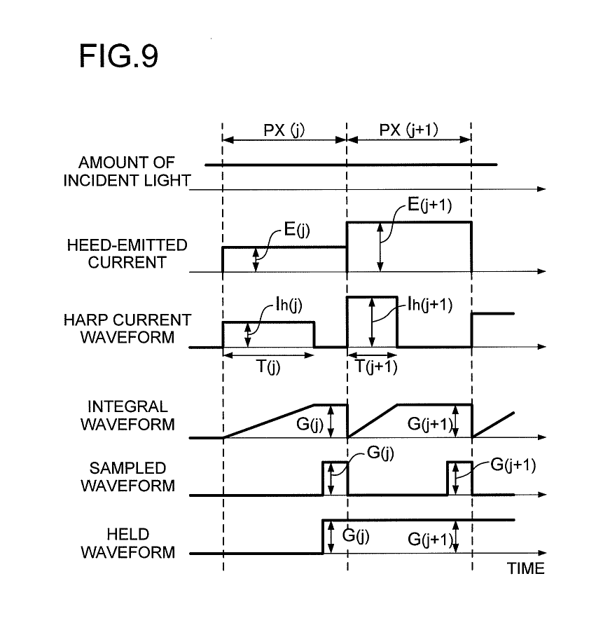

FIG. 9 illustrates the case where the amounts of light incident on the pixel regions of the HARP photoelectric conversion film 11 are equal and the amount of electrons emitted from the elements of the HEED cold cathode array 20 are different, more specifically, the amounts of HEED-emitted electrons (or emitted currents) are such that E(j)<E(j+1). Here, the HARP current values (pulse heights) are such that Ih(j)<Ih(j+1), while the HARP current periods are such that T(j)>T(j+1).

The integrator 55 integrates a HARP current for each of the pixel periods PX(j) and PX(j+1) while performing reset of the integrated value when each pixel period terminates. The integrated values of the HARP currents are such that Ih(j)×T(j)=Ih(j+1)×T(j+1) after holes stored in each pixel region are completely neutralized. That is, the integrated values after the periods T(j) and T(j+1) elapse have equal constant values G(j) and G(j+1) (i.e., G(j)=G(j+1)) according to the amounts of incident light.

The sample/hold circuit 56 samples an integral waveform of a HARP current in a predetermined sampling period ST at an end portion of each pixel period and holds the sampled value. That is, the sample/hold circuit 56 performs sampling after the integrated value becomes constant at an end portion of each pixel period. Since the sample/hold circuit 56 performs sampling after neutralization of holes stored in the pixel regions by emitted electrons is completed, it is possible to obtain accurate integrated values (or pixel values) G(k) according to the amounts of incident light even when the amounts of electrons emitted from the HEED cold cathode array elements (i.e., the HARP current periods) are different. The sample/hold circuit 56 then outputs the pixel values G(k) (k=1, 2, . . . ) as an image signal SV. Thus, the image signal detector 51 can generate an accurate image signal according to the amounts of light incident on the pixel regions of the HARP photoelectric conversion film 11. In addition, there is no noise due to variation of the amount of emitted electrons since the integrator 55 is used.

The above description with reference to FIG. 9 has been given for the case where the amounts of light incident on the pixel regions are equal and the amounts of emitted electrons are different. However, when the amounts of light incident on the pixel regions are different and the amounts of electrons emitted from the elements of the HEED cold cathode array 20 are different, it is also possible to obtain accurate integrated values according to the amounts of incident light without noise due to variation of the amounts of emitted electrons as is understood from the above description.

As described above, the conventional configuration using an LPF for signal detection has a problem in that an image signal has noise due to variation of the amounts of electrons emitted from electron emission elements. However, according to the present invention, it is possible to generate an image signal which has no noise even when there is variation in the amount of emitted electrons as described above and thus has a high signal to noise ratio (S/N) and a high image quality.

### Embodiment 2

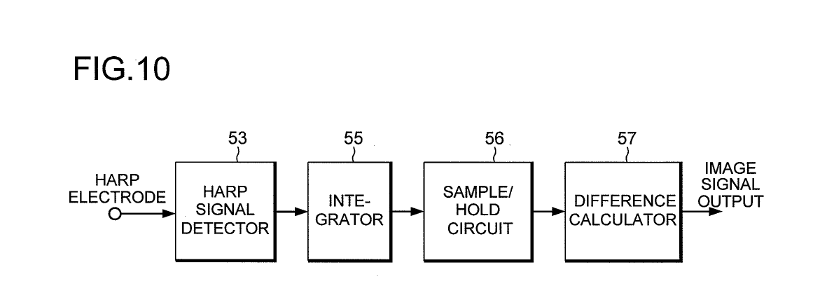

FIG. 10 is a block diagram illustrating a configuration of an image signal detector 51 according to Embodiment 2 of the present invention. The image signal detector 51 includes a HARP signal detector 53, an integrator 55, a sample/hold circuit 56, and a difference calculator 57.

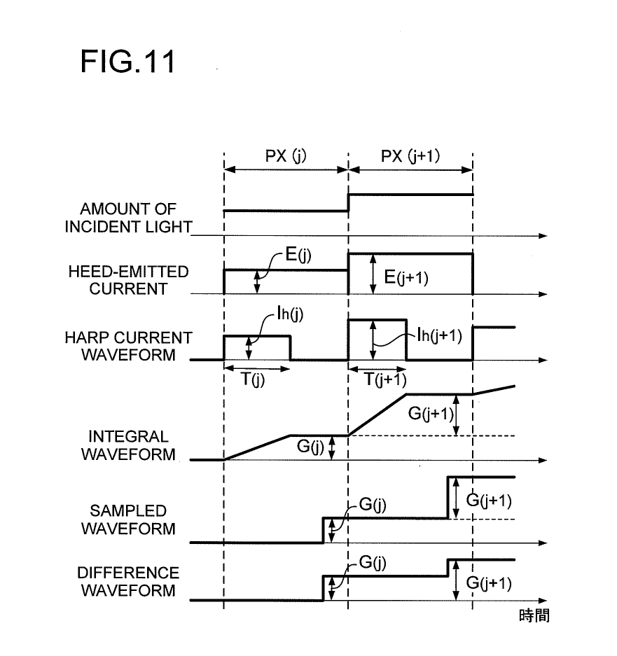

FIG. 11 schematically illustrates output signal waveforms of the components of the image signal detector 51 when the amounts of light incident on pixel regions of the HARP photoelectric conversion film 11 are different and the amounts of electrons emitted from elements of the HEED cold cathode array 20 are different. That is, similar to the above embodiment, the amounts of HEED-emitted electrons (or emitted currents) are such that E(j)<E(j+1) and the HARP current values (pulse heights) are such that Ih(j)<Ih(j+1). However, G(j) (=Ih(j)×T(j)) and G(j+1) (=Ih(j+1)×T(j+1)) are different since the amounts of light incident on the pixel regions are different. In the illustrated case, G(j)<G(j+1).

Embodiment 1 has been described with reference to the case where the integrator 55 is configured such that it integrates the HARP current for each of the pixel periods PX(j) and PX(j+1) while resetting the integrated value when each pixel period terminates. In this embodiment, the integrator 55 integrates the HARP current over a predetermined period. That is, the integrator 55 may be configured such that it continues integrating the HARP current over a predetermined number of pixel periods and performs an operation for resetting the integral signal (integrated value) upon termination of the last pixel period of each predetermined number of pixel periods.

Alternatively, the integrator 55 may be configured such that it continues integrating the HARP current over a scan period of a horizontal scan line Yk (i.e., the k-th scan line), which is the predetermined period, and performs the reset operation each time a horizontal scan line is scanned. The following description will be given with reference to an example in which the integrator 55 performs the reset operation each time a horizontal scan line is scanned.

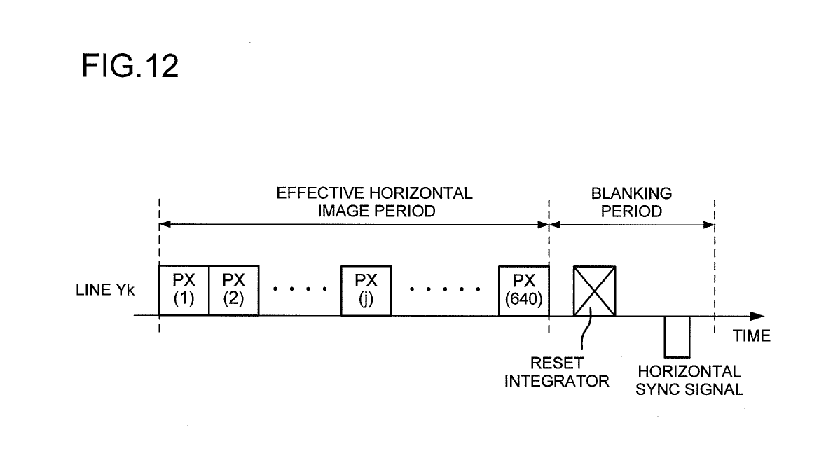

FIG. 12 schematically illustrates how the integrator 55 performs an integration operation and an integral reset operation when dot-sequential scanning is performed on pixels PX(j) (j=1 to m, m=640 in this example) of a horizontal scan line Yk (k=1 to n) through a scanning operation of the horizontal scan line Yk in the X direction (i.e., the horizontal direction). That is, the integrator 55 continues integrating the HARP current over one effective horizontal scan period and performs a reset operation in an image blanking period after scanning of the scan line (Yk). In this manner, the integrator 55 repeats the integration operation and the reset operation for each scan line from the first scan line Y1 to the n-th scan line Yn under control of the controller 25.

The sample/hold circuit 56 samples an integral waveform of a HARP current in a predetermined sampling period ST at an end portion of each pixel period and holds the sampled value. Since the sample/hold circuit 56 performs sampling at an end portion of each pixel period at which neutralization of holes stored in the pixel regions is completed, it is possible to obtain accurate integrated values according to the amounts of incident light even when the amounts of electrons emitted from the HEED cold cathode array elements are different. The sample/hold circuit 56 provides the sampled value of each pixel period PX(j) (j=1−m) to the difference calculator 57.

As shown in FIG. 11, the difference calculator 57 calculates a difference between an integrated value of a previous pixel PX(j−1) and an integrated value of the current pixel PX(j) and determines the difference to be the pixel luminance (pixel value) G(j) of the current pixel PX(j). The difference calculator 57 sequentially outputs pixel values G(k) (k=1, 2, . . . ) and obtains an image signal SV.

In this embodiment, the integrator 55 performs the reset operation in a blanking period subsequent to an effective horizontal scan period which is not a pixel period. For example, nanoseconds to tens of nanoseconds may be required to drain charge from the integrator 55 in the reset operation of the integrator 55. In this embodiment, no reset period is set in each pixel period and the reset operation is performed in a blanking period.

In addition, in the case where the integrator 55 is configured to continue integration of the HARP current over a predetermined number of pixel periods and to perform the reset operation in each predetermined number of pixel periods, the difference calculator 57 may be configured to calculate the difference between the previous and current pixels.

According to this embodiment, there is no need to set a reset period in each pixel period as described above and therefore it is possible to set a short pixel period and thus to provide an image sensing device capable of performing high-speed operation. In addition, similar to the above embodiment, it is possible to generate an image signal which has no noise even when there is variation in the amount of emitted electrons and thus a high signal to noise ratio (S/N) and has a high image quality.

### Embodiment 3

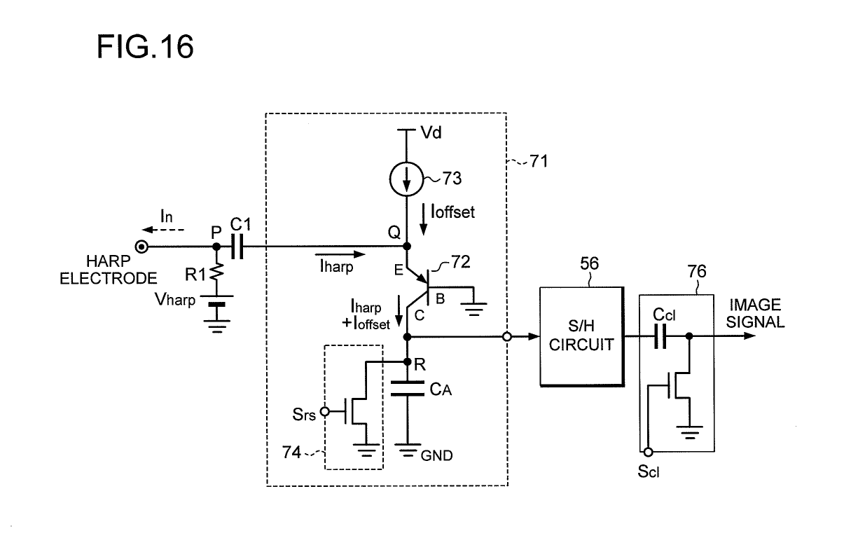

FIG. 16 is a block diagram illustrating a configuration of an integration type detector 71 according to Embodiment 3 of the present invention. The integration type detector 71 operates as both a HARP signal detector and an integrator. More specifically, the integration type detector 71 includes a transistor for receiving current 72, an offset current source 73 including a constant current source, a storage capacitor C that operates as a current integrator, and a reset circuit 74. An output of the integration type detector 71 is provided to a sample/hold circuit (S/H) 56 and an output of the sample/hold circuit 56 is output as an image signal through a clamp circuit 76. Similar to the above embodiments, the integration type detector 71 operates under control of the controller 25.

Although the following description is given with reference to an example in which a bipolar transistor is used as the transistor for receiving current 72, which will also be simply referred to as a “transistor 72”, a different element such as a Field Effect Transistor (FET) may also be used. In this embodiment, the transistor 72 has a so-called grounded-base circuit structure. Although FIG. 16 illustrates the case where a base (B) of the transistor 72 is grounded (GND), the base may also be fixed to a specific base voltage (V_{B}). In the grounded-base circuit structure, while the base electrode voltage is fixed and the emitter (E) electrode is used as a current injection terminal, an emitter current injected to the emitter electrode from the HARP photoelectric conversion film (HARP electrode) 11 through the capacitor C1 is output through the collector (C) electrode, thereby stabilizing the voltage of the current injection terminal. With the voltage of the current injection terminal stabilized, it is possible to detect a stable output current. That is, the transistor 72 operates as a photoelectric conversion film current detector. When an FET is used as the transistor 72, a gate, a source, and a drain of the FET correspond respectively to the base, the emitter, and the collector.

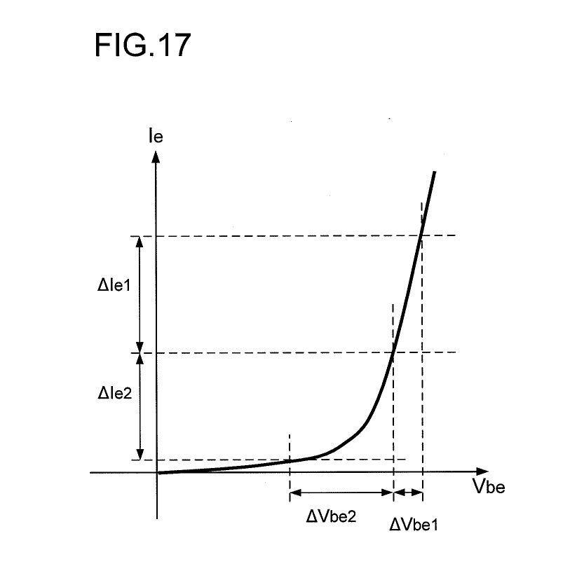

FIG. 17 schematically illustrates characteristics of the current receiving transistor 72, specifically, the relation between an emitter current Ie and a base-to-emitter voltage Vbe. When the emitter current Ie is large, a change (ΔVbe1) of the base-to-emitter voltage Vbe with respect to a change (ΔIe1) of the emitter current Ie is small. That is, in this case, impedance is small (i.e., the slope of Ie-Vbe characteristics is large) and voltage change of the emitter (corresponding to a point “Q” in FIG. 16) is small. On the other hand, when the emitter current Ie is small, a change (ΔVbe2) of the base-to-emitter voltage Vbe with respect to a change (ΔIe2) of the emitter current Ie is large (i.e., impedance is large). However, since the emitter electrode is connected to the HARP electrode (HARP photoelectric conversion film) 11 through the coupling capacitor C1, the change component of the base-to-emitter voltage Vbe is also applied to the HARP photoelectric conversion film 11 through capacitive coupling of the capacitor C1. Since the change component is AC and also has pulse characteristics as described above, it causes noise while disturbing the HARP voltage (Vharp). Since the HARP voltage Vharp is closely related to the sensitivity of the HARP photoelectric conversion film 11, disturbing the voltage applied to the HARP photoelectric conversion film 11 also disturbs the detection sensitivity.

In addition, the HARP detection current is an AC (alternating current) component detected through capacitive coupling and thus current may flow in the negative direction (see “current In” shown by a dashed arrow in FIG. 16). Accordingly, detection gain changes or distortion occurs when the current direction shifts from negative to positive or from positive to negative.

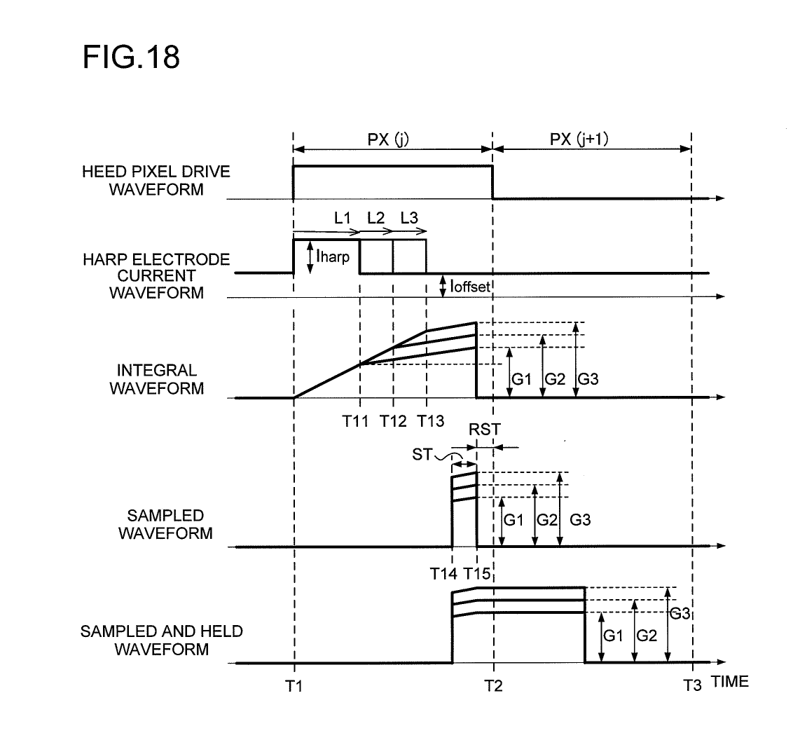

FIG. 18 schematically illustrates respective output signal waveforms of the components of this embodiment. As shown in FIG. 16, the offset current source 73 is provided to superimpose an offset current (Ioffset) onto the HARP electrode current. In another words, as shown in FIG. 16, the offset current Ioffset is superimposed onto the HARP electrode current (i.e., detection current) Iharp flowing into the emitter electrode of the transistor 72 through the coupling capacitor C1. This allows the transistor 72 to operate within an operation range in which the change of the base-to-emitter voltage Vbe with respect to change of the emitter current is small (i.e., impedance is small). That is, change of the potential of the emitter electrode (corresponding to the HARP current detection point “Q” in FIG. 16) is small, thereby reducing the change of the potential toward the HARP voltage Vharp through the coupling capacitor C1. Accordingly, it is possible to suppress the disturbance of the detection current and sensitivity of the HARP photoelectric conversion film 11.

As shown in FIG. 18, in the pixel period PX(j), the offset current Ioffset is superimposed onto the HARP electrode current Iharp and the resulting current (Iharp+Ioffset) is stored (or integrated) in a storage capacitor C_{A} that operates as a current integrator. For better understanding and ease of explanation, FIG. 18 illustrates the output signal waveforms for three levels of luminance L1, L2, and L3 (L1<L2<L3) in the pixel period PX(j) in an overlapping manner. That is, when the luminance of the pixel period PX(j) is L1, time-integration of the superimposed current (Iharp+Ioffset) starts at a start point (T1) of the pixel period PX(j) and the integration of the superimposed current terminates at a time T (T=T11) at which neutralization of holes is completed and then integration is performed only on the offset current Ioffset until a predetermined integration termination time T15 is reached. The sample/hold circuit 56 samples the integral waveform in a sampling period ST (T=T14-T15) which ends at the integration termination time T15 and holds the sampled value. The reset circuit 74 resets the integrated value in a reset period RST (T=T15-T2) which is an end portion of the pixel period PX(j). For example, the reset circuit 74 includes a switch connected in parallel between both ends of the storage capacitor C_{A} and electrically connects both ends of the capacitor C_{A} according to a control signal (reset signal) Srs from the controller 25 to discharge charge stored in the capacitor, thereby performing the reset operation. For example, the reset circuit 74 may be constructed of a transistor such as an FET.

Through the above operation, the integrated value of the offset current Ioffset of the period of T=T11 to T2 is added to the integrated value of the period of T=T1 to T11 (i.e., the duration of the HARP current) to obtain an integrated value G1 at the end time (T2) of the pixel period PX(j). The same is true for both the cases where the luminance of the pixel period PX(j) is L2 and L3. In both the cases, a HARP current onto which an offset current has been superimposed in respective durations T (=T1-T12) and T (=T1-T13) of the HARP current is integrated and then integration is performed only on the offset current Ioffset until the time T (=T14), at which the sampling period ST of the pixel period PX(j) starts, is reached to obtain respective integrated values G2 and G3. Operations for sampling an integral waveform of the sampling period ST (T=T14-T15) and holding the sampled value and an operation for resetting the integrated value in a reset period RST (T=T15-T2) which is an end portion of the pixel period PX(j) are also performed in the same manner as described above. These integration, sample/hold, and integral reset operations are performed on each of the pixel periods PX(j) (j=1, 2, 3, . . . ) to obtain an image signal, similar to the above embodiments.

It is preferable that the offset current Ioffset have a value allowing the HARP current to always be positive according to the amount of electrons emitted from the HEED electrode emission sources. That is, it is preferable that the offset current Ioffset be larger than (the absolute value of) the HEED-emitted current. Specifically, it is preferable that the offset current Ioffset be larger than current caused by electrons emitted from one pixel (corresponding to a total of electrons emitted from an emission site ES of one pixel).

In this embodiment, the integral output from the integration type detector 71 is output as an image signal through the sample/hold circuit 56 and the clamp circuit 76. For example, the clamp circuit 76 may be constructed as a circuit including a capacitor Cc1 connected in series to the output of the sample/hold circuit 56 and a transistor such as an FET provided between an image signal output line and ground (GND) as shown in FIG. 16. When the AC signal is reproduced, the DC level is not fixed. Thus, clamping is performed on the output (i.e., image signal output) of the sample/hold circuit 56 to fix the DC level (i.e., fix the DC level to 0V of the black level when the signal is an image signal). That is, the clamp circuit 76 performs an operation for removing the DC deviation remaining in the output of the integration type detector 71.

Specifically, in a blanking period of horizontal scanning during which the level of luminance of the image signal should be zero, the switch of the clamp circuit 76 is turned on and the image signal output voltage is connected to 0V (i.e., ground). That is, the voltage in a blanking period in which the level of luminance is zero is clamped such that it is forcibly fixed to 0V. Then, the switch of the clamp circuit 76 is turned off. Through this clamp operation, it is possible to obtain an image luminance level (voltage difference) relative to the clamped level (i.e., the black level corresponding to 0V), i.e., to generate an image signal having accurate luminance with the clamped level being used as a reference image luminance level (corresponding to zero luminance), i.e., as a black level. For example, the clamp operation may be set to be performed according to a control signal (specifically, a clamp signal Sc1) from the controller 25. The circuit configuration of the clamp circuit 76 is merely illustrative and the circuit of the clamp circuit 76 may employ any configuration which allows the reference image luminance level to be fixed to a predetermined DC level such as 0V in a period such as a blanking period in which the image signal has a black level (i.e., a luminance level of zero).

As is apparent from the above description, according to the embodiment, an offset current is superimposed onto the HARP signal current, and therefore it is possible to suppress change of voltage of the current detection terminal due to change of the signal current and to suppress change of the voltage toward the voltage of the capacitor-coupled HARP electrode. Accordingly, it is possible to provide an image device that suppresses disturbance of luminance detection current and sensitivity and thus generates an image signal having a high signal to noise ratio (S/N) and a high image quality.

The above embodiments may be appropriately combined and applied. Although the above embodiments have been described with reference to examples in which an HEED cold cathode array is used as a cold cathode array and a HARP photoelectric conversion film is used as a photoelectric conversion film, the present invention may also be applied to any image sensing device that uses any of a variety of cold cathode arrays, electron supply sources, and photoelectric conversion films. Materials, numerical values, and the like described in the above embodiments are only illustrative.

1. An image sensing device comprising:
a photoelectric conversion film that generates holes corresponding to incident light through avalanche multiplication;
an electron supply source array including a plurality of electron supply sources arranged in a matrix;
a scan driver which scans the electron supply source array to sequentially supply electrons to a plurality of pixel regions of the photoelectric conversion film;
a photoelectric conversion film current detector coupled to the photoelectric conversion film through a capacitor, the photoelectric conversion film current detector detecting photoelectric conversion film current that flows as holes generated in the photoelectric conversion film combine with electrons supplied from the electron supply source array to the photoelectric conversion film;
an offset current source which generates an offset current and superimposes the offset current on the photoelectric conversion film current;
an integrator which performs time-integration of the resultant current to generate an integration signal; and
a sampling unit which samples the integration signal in each of respective pixel periods of the pixel regions, in which electrons are supplied to the pixel regions, to generate an image signal.

2. The image sensing device according to claim 1, further comprising a reset unit which resets the integration signal in each of the pixel periods.

3. The image sensing device according to claim 1, wherein the offset current is larger than a current of each of the electron supply sources.

4. The image sensing device according to claim 1, further comprising a clamp circuit which clamps a sampling output terminal of the sampling unit to a ground potential in a blanking period when the electron supply source array is scanned.
